(19) United States
(12) Patent Application Publication
(10) Pub. No.: US 2018/0287653 A1
(43) Pub. Date: Oct. 4, 2018

(54) Method For Manufacturing Clearance Area Of Housing, Housing, And Mobile Terminal

(71) Applicant: Guangdong Oppo Mobile Telecommunications Corp., Ltd., Dongguan (CN)

(72) Inventors: Jing Li, Dongguan (CN); Guangming Yang, Dongguan (CN)

(21) Appl. No.: 15/997,198

(22) Filed: Jun. 4, 2018

Related U.S. Application Data
(63) Continuation-in-part of application No. PCT/CN2017/077165, filed on Mar. 18, 2017.

(30) Foreign Application Priority Data
Mar. 18, 2016 (CN) 201610157104.2

(51) Int. Cl. H04B 1/3888; B23K 26/38; H04M 1/02; H05K 9/00

(52) U.S. Cl. CPC H04B 1/3888; H05K 9/0007; H04M 1/0202; B23K 26/38

(57) ABSTRACT

Methods, housings and mobile terminals for manufacturing a clearance area of a housing include: providing a housing made of a signal shielding material and having a predetermined area, wherein the housing in the predetermined area has a first surface and a second surface opposite to the first surface; forming at least one support structure on the first surface protruding from the first surface; cutting the first surface by a laser cutter to form a predetermined number of micro slits penetrating from the first surface to the second surface and being spaced with each other and arranged side-by-side, wherein each of the at least one support structure stretches across the predetermined number of micro slits to connect the housing into a whole; filling each of the predetermined number of micro slits with a non-signal shielding material to obtain a clearance area; and cutting off the at least one support structure.

### CROSS-REFERENCE TO RELATED APPLICATION(S)

This application is a continuation-in-part of International Application No. PCT/CN2017/077165, filed on Mar. 18, 2017, which claims priority to Chinese Patent Application No. 201610157104.2, filed on Mar. 18, 2016, the contents of both of which are hereby incorporated by reference in their entireties.

### TECHNICAL FIELD

This disclosure relates to the field of electronic devices, especially relates to a method for manufacturing a clearance area of a housing, a housing, and a mobile terminal.

### BACKGROUND

With the improvement of science and technology, and the requirement of market, a demand for full metal mobile phones is more and more strong. The full metal mobile phones is beautiful, but, a full metal housing will block a radio-frequency signal of an antenna.

In related art, a certain clearance area is manufactured by a numerical control machine on back of the full metal mobile phones, to let the radio-frequency signal passing through. But the inventor finds that, when performing the above process, it is impossible to machine a clearance area with certain shape, or the clearance area is too large to preserve appearance integrity of the mobile phone, due to limitations of a numerical control machine tool or a control mode.

### SUMMARY

The disclosure provides a method for manufacturing a clearance area of a housing, which can machine a housing with a clearance area having certain shape, and can preserve the appearance integrity of the housing.

Embodiments of the present disclosure provide a method for manufacturing a clearance area of a housing. The method includes: providing a housing, the housing being made of signal shielding material and defining a predetermined area, and the housing in the predetermined area having a first surface and a second surface opposite to the first surface; forming at least one support structure on the first surface in the predetermined area, whereby the at least one support structure protrudes from the first surface; cutting out, on the second surface, a predetermined number of micro slits by using a laser cutter, the predetermined number of micro slits penetrating from the first surface to the second surface and being spaced with each other and arranged side-by-side, each of the at least one support structure stretching across the predetermined number of micro slits, to connect the housing into a whole; filling each of the predetermined number of micro slits with non-signal shielding material, to obtain a clearance area; and cutting off the at least one support structures.

Embodiments of the disclosure further provides a housing. The housing is made of a signal shielding material and defines a predetermined area; the predetermined area is provided with a predetermined number of micro slits, the predetermined number of micro slits is spaced with each other and is arranged side-by-side; each of the predetermined number of micro slits is filled with a non-signal shielding material to obtain a clearance area, the clearance area is configured for radio frequency signal of an antenna to pass through.

Embodiments of the disclosure further provides a mobile terminal including a housing. The housing is made of a signal shielding material and defines a predetermined area; the predetermined area is provided with a predetermined number of micro slits, the predetermined number of micro slits is spaced with each other and is arranged side-by-side; each of the predetermined number of micro slits is filled with a non-signal shielding material to obtain a clearance area, the clearance area is configured for radio frequency signal of an antenna to pass through.

### BRIEF DESCRIPTION OF THE DRAWINGS

To describe the technical solutions in the embodiments of the present disclosure more clearly, the following briefly introduces the accompanying drawings required for describing the embodiments. It will be apparent that, the following described drawings are merely illustrative of the present disclosure. It will be apparent to those skilled in the art that other drawings can be obtained from the drawings without any creative work.

FIG. 1 is a flowchart illustrating a method for manufacturing a clearance area of a housing, according to one embodiment of the disclosure.

FIG. 2 is a flowchart illustrating another method for manufacturing a clearance area of a housing, according to one embodiment of the disclosure.

FIG. 3 is a schematic view of a housing, according to one embodiment of the disclosure.

FIG. 4 is a schematic view of manufacturing at least one support structure on the housing of FIG. 3, according to one embodiment of the disclosure.

FIG. 5 is a schematic view of forming predetermined number of micro slits on the housing of FIG. 4, according to one embodiment of the disclosure.

FIG. 6 is a schematic view of filling a non-signal shielding material in each of the predetermined number of micro slits in FIG. 5, according to one embodiment of the disclosure.

FIG. 7 is a schematic view of cutting off the at least one support structures in FIG. 6, according to one embodiment of the disclosure.

### DETAILED DESCRIPTION

The present disclosure will now be described in detail and completely with reference to the accompanying drawings of the embodiments. It is to be understood that the specific embodiments described herein are merely illustrative but not all embodiments of the disclosure. Any other embodiments that can be obtained by a person skilled in the art without creative work according to the embodiments in the present disclosure shall be all covered within the protection of the disclosure.

In description of the embodiments of the disclosure, it will be appreciated that, locations or positions indicated by terms “transverse”, “longitudinal”, “length” and “width” are locations or positions based on the drawings, and those terms are merely used to conveniently describe the disclosure and to simplify the description, and are not intended to imply or indicate that the referring devices or components must having a specific location and must structuring and operating in a specific location, therefore, those terms cannot be interpreted as a limitation to the disclosure.

A method for manufacturing a clearance area of a housing. The method includes: providing a housing, the housing being made of signal shielding material and defining a predetermined area, and the housing in the predetermined area having a first surface and a second surface opposite to the first surface; forming at least one support structure on the first surface in the predetermined area, whereby the at least one support structure protrudes from the first surface; cutting out, on the second surface, a predetermined number of micro slits by using a laser cutter, the predetermined number of micro slits penetrating from the first surface to the second surface and being spaced with each other and arranged side-by-side, each of the at least one support structure stretching across the predetermined number of micro slits, to connect the housing into a whole; filling each of the predetermined number of micro slits with non-signal shielding material, to obtain a clearance area; and cutting off the at least one support structures.

A housing is made of a signal shielding material and defines a predetermined area; the predetermined area is provided with a predetermined number of micro slits, the predetermined number of micro slits is spaced with each other and is arranged side-by-side; each of the predetermined number of micro slits is filled with a non-signal shielding material to obtain a clearance area, the clearance area is configured for radio frequency signal of an antenna to pass through.

A mobile terminal includes a housing. The housing is made of a signal shielding material and defines a predetermined area; the predetermined area is provided with a predetermined number of micro slits, the predetermined number of micro slits is spaced with each other and is arranged side-by-side; each of the predetermined number of micro slits is filled with a non-signal shielding material to obtain a clearance area, the clearance area is configured for radio frequency signal of an antenna to pass through.

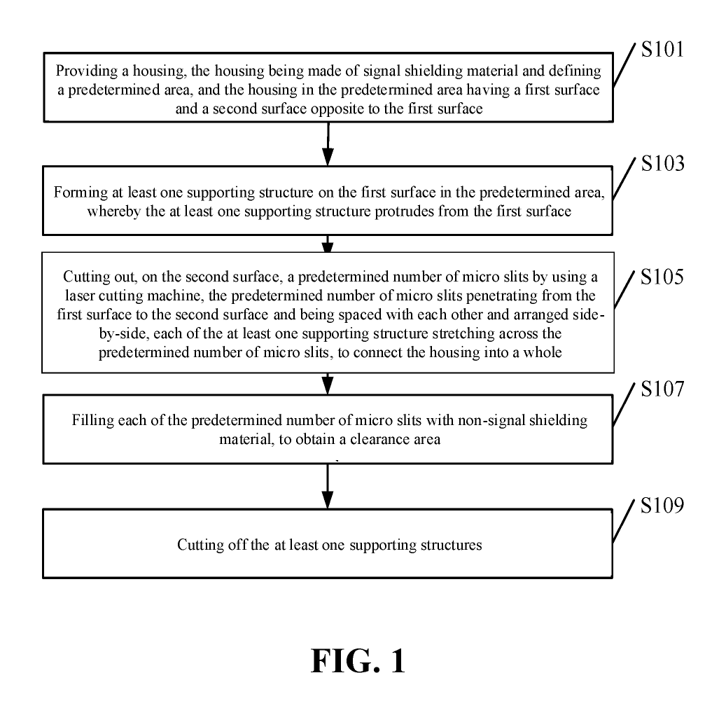

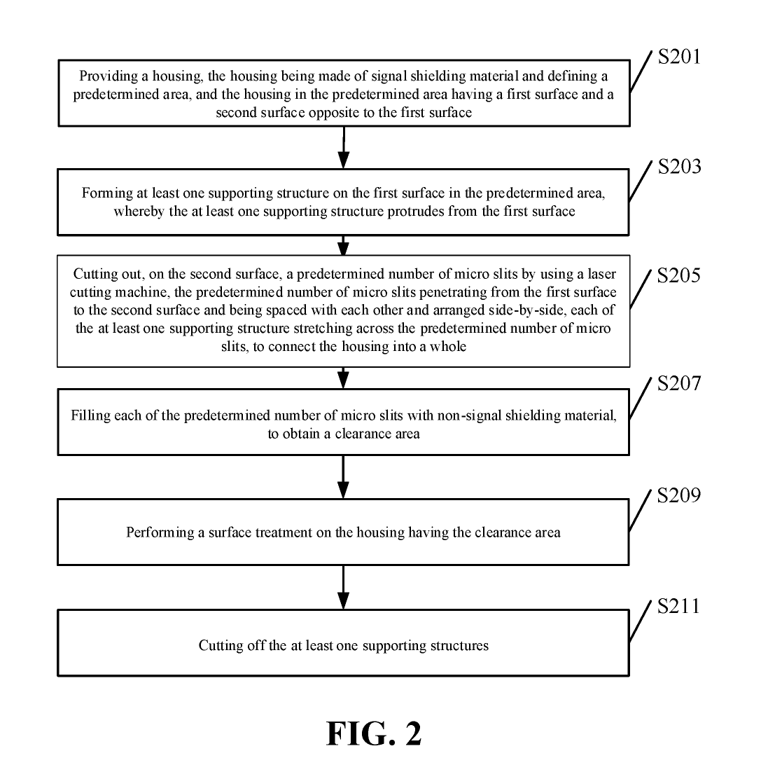

A method for manufacturing a clearance area of a housing is described in detail below with reference to FIG. 1 to FIG. 2.

Referring to FIG. 1, FIG. 1 is a flowchart illustrating the method for manufacturing the clearance area of the housing, according to one embodiment of the disclosure. As illustrated in FIG. 1, the method for manufacturing the clearance area of the housing in this exemplary embodiment can includes the following actions at block S101 to block S109.

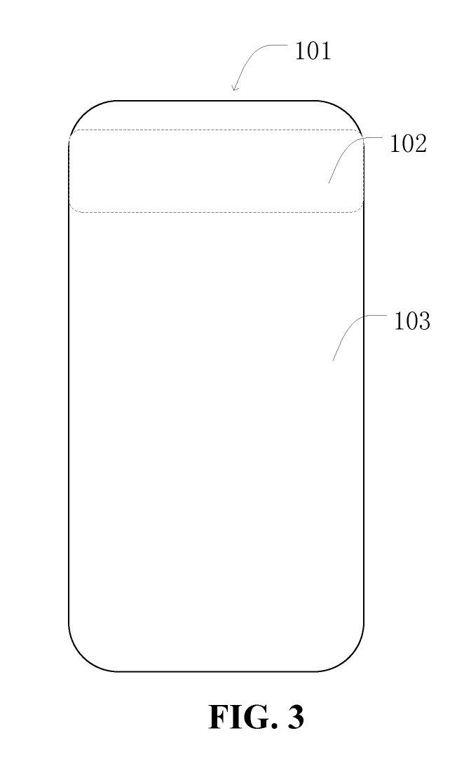

At block S101: further referring to FIG. 3, a housing 101 is provided. The housing 101 is made of a signal shielding material, and defines a predetermined area 102. The housing 101 in the predetermined area 102 has a first surface 103 and a second surface (not shown) opposite to the first surface 103.

Specifically, the housing 101 can be made according to actual needs. It will be apparent that, the housing 101 can be a rear cover of a mobile terminal. The predetermined area 102 is at a certain region of the housing 101 according to actual needs. The predetermined area 102 is a certain region of the housing 101 needing to let the radio frequency signal passing through. The first surface 103 can be an inner surface of the rear cover, and the second surface can be an outer surface of the rear cover. The outer surface is exposed to the air, that is, the outer surface is a surface can be directly contact by user. In other exemplary embodiments, the housing 101 can be a rear housing or a back cover with a border.

In one exemplary embodiment, the housing 101 can be manufactured by the following method: a metal plate is received in a mold and is stamped into a metal board having a predetermined shape; an inner structure and an outer shape of the metal board having the predetermined shape are processed by a numerical control machine, to obtain the housing 101. The metal plate is an aluminum plate. A large aluminum plate panel is cut into a plurality of small aluminum plates. The cut aluminum plates are received in a mold for pressing to form metal boards with the predetermined shape. It will be apparent that, the aluminum plate can be pressed once or can be continuously pressed for multiple times. The metal board is processed by a numerical control machine to obtain a demand housing 101.

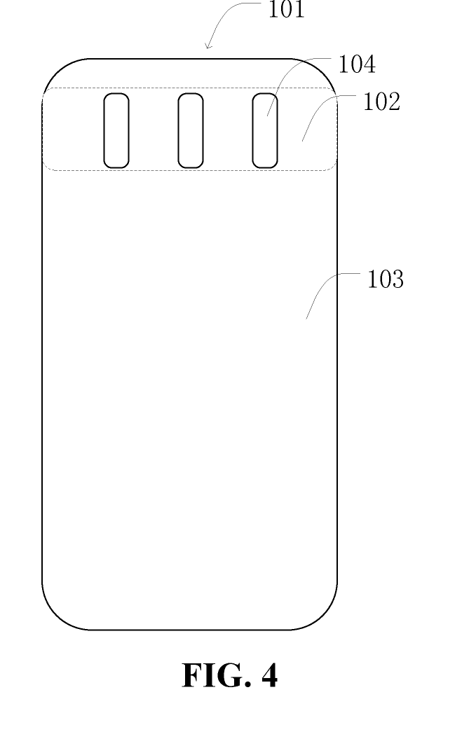

At block S103: further referring to FIG. 4, at least one support structure 104 is manufactured on the first surface 103 in the predetermined area 102, whereby the at least one support structure 104 protrudes from the first surface 103.

Specifically, an extending direction of the at least one support structure 104 is a longitudinal direction of the housing 101. The at least one support structure 104 is defined to be three support structures 104. The three support structures 104 are spaced with each other and are sequentially arranged on the first surface 103 in the predetermined area 102 along a transverse direction of the housing 101. The first surface 103 is the inner surface. The transverse direction is a width direction. Thus, when cutting off the three support structures 104 later, a cutting mark left on the first surface 103 will be located inside the mobile terminal. The cutting mark can only be observed when disassembled the mobile terminal, therefore, the cutting mark will not undermine the appearance integrity of the mobile terminal. It will be apparent that, each of the at least one support structure 104 is shaped as a bridge pier, to avoid a deformation on the housing 101 in a laser cutting process. In other embodiments, the at least one support structure 104 can be other structures, as long as the at least one support structure 104 can provide a supporting, for example, the at least one support structure 104 is at least a stiffener or at least a rib. In other embodiments, other numbers of the at least one support structures can be provided.

At block S105: a laser cutter aims on and cuts the second surface of the predetermined area 102, to form a predetermined number of micro slits. The predetermined number of micro slits are spaced with each other and are arranged side-by-side. Each of the at least one support structure 104 stretches across the predetermined number of micro slits, to connect the housing 101 into a whole.

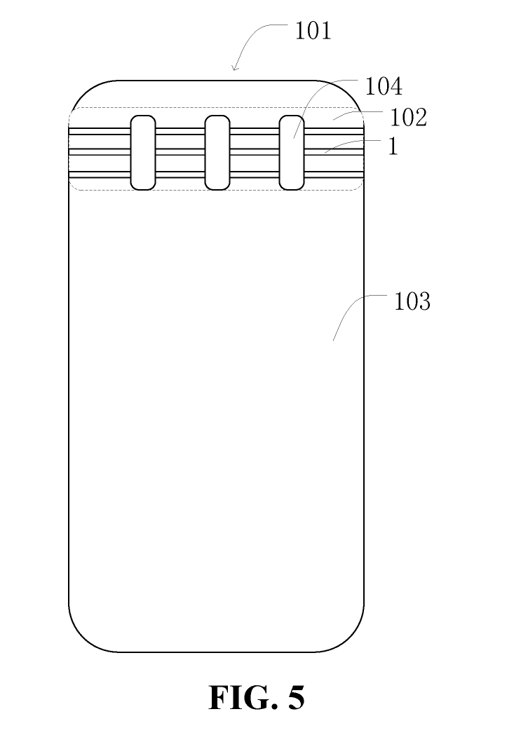

Specifically, further referring to FIG. 5, an extending direction of the predetermined number of micro slits 1 is a transverse direction of the housing 101. Lasers of an optical fiber laser cutter of large power is used to cut the housing 101 from the first surface 103 to penetrate the second surface, to form the predetermined number of micro slits 1. The predetermined number of micro slits 1 is defined to be three micro slits 1. The three micro slits 1 are spaced with each other and are sequentially arranged along a longitudinal direction of the housing 101, which is also a length direction. Wherein, through a lot of experiments, the inventor develops that, through the method of embodiments of the disclosure, a width of each of the predetermined number of micro slits 1 can be in a range from 0.05 millimeters to 0.15 millimeters, that is, the predetermined number of micro slits 1 is barely visible to the naked eye, which can ensure the radio frequency signal of the antenna of the mobile terminal to pass through and can improve an integrity of outer structure of the housing 101. In this exemplary embodiment, the width of each of the predetermined number of micro slits 1 is 0.06 millimeters. Each of the at least one support structures 104 stretches across the three micro slits 1, that is each of the at least one support structure 104 covers the three micro slits 1, to form a good support structure 104. In other embodiments, other numbers of the predetermined number of micro slits 1 can be provided.

In one exemplary embodiment, an auxiliary cooling processing is performed during a laser cutting processing, to lower the temperature in the laser cutting processing, to form the remand micro slits 1. It will be apparent that, the auxiliary cooling processing can be a high-pressure nitrogen-assisted cooling processing.

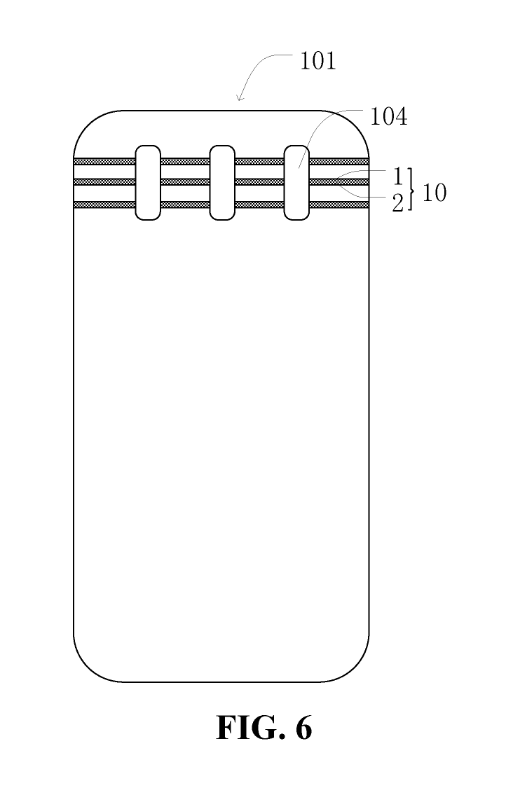

At block S107: further referring to FIG. 6, a non-signal shielding material 2 is filled in each of the predetermined number of micro slits 1, to obtain a clearance area 10.

Specifically, the housing 101 having the clearance area 10 is etched. Wherein, the non-signal shielding material 2 is a material which can let the radio frequency signal passing through. It will be apparent that, the non-signal shielding material 2 can be plastic. Wherein, nano-injection filling is performed on each of the predetermined number of micro slits 1, to obtain the clearance area 10. The radio frequency signal can pass through each of the predetermined number of micro slits 1 filled with the non-signal shielding material 2, that is, the predetermined number of micro slits 1 forms to be the clearance area 10 of the antenna.

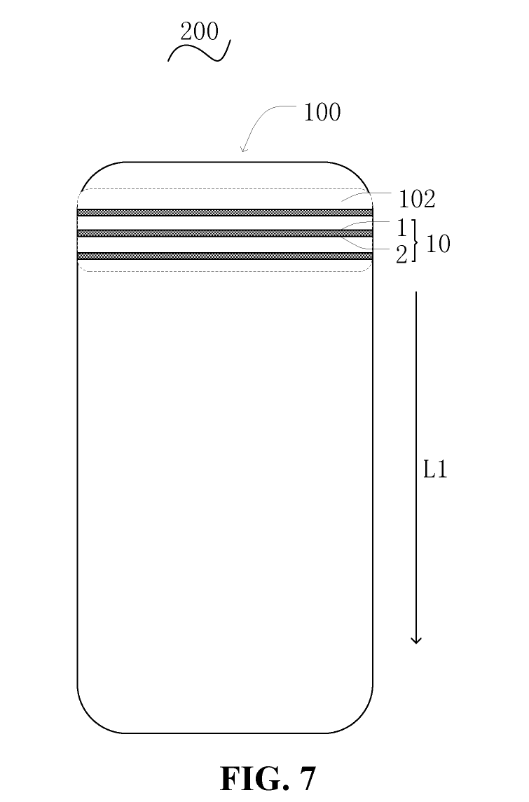

At block S109: further referring to FIG. 7, the at least one support structures 104 is cut off.

Specifically, the at least one support structures 104 is cut off by a numerical control machine, and structures on other portions of the housing 101 are simultaneously finished, to obtain a housing 100.

The method for manufacturing the clearance area of the housing provided by embodiments of the disclosure, includes cutting the housing to obtain a predetermined number of micro slits by laser, and filling a non-signal shielding material in each of the predetermined number of micro slits to form the clearance area, which can obtain the clearance area with a certain shape; and for the width of the predetermined number of micro slits is small, a usage of the non-signal shielding material is reduced, and that can preserve the appearance integrity of the housing.

Referring to FIG. 2, FIG. 2 is a flowchart illustrating another method for manufacturing a clearance area of a housing, according to one embodiment of the disclosure. As illustrated in FIG. 2, the method for manufacturing the clearance area of the housing in this embodiment can includes the following actions at block S201 to block S211.

At block S201: further referring to FIG. 3, a housing 101 is provided. The housing 101 is made of a signal shielding material, and defines a predetermined area 102. The housing 101 on the predetermined area 102 has a first surface 103 and a second surface (not shown) opposite to the first surface 103.

Specifically, the housing 101 can be made according to actual needs. It will be apparent that, the housing 101 can be a rear cover of a mobile terminal. The predetermined area 102 is at a certain region of the housing 101 according to actual needs. The predetermined area 102 is a certain region of the housing 101 needing to let the radio frequency signal passing through. The first surface 103 can be an inner surface of the rear cover, and the second surface can be an outer surface of the rear cover. The outer surface is exposed to air, that is the outer surface is a surface can be directly contact by user. In other exemplary embodiments, the housing 101 can be a rear housing or a back cover with a border.

In one exemplary embodiment, the housing 101 can be manufactured by the following method: a metal plate is received in a mold and is stamped into a metal board having a predetermined shape; an inner structure and an outer shape of the metal board having the predetermined shape are processed by a numerical control machine, to obtain the housing 101. The metal plate is an aluminum plate. A large aluminum plate panel is cut into a plurality of small aluminum plates. The cut aluminum plates are received in a mold for pressing to form metal boards with the predetermined shape. It will be apparent that, the aluminum plate can be pressed once or can be continuously pressed for multiple times. The metal board is processed by a numerical control machine to obtain a demand housing 101.

At block S203: further referring to FIG. 4, at least one support structure 104 is manufactured on the first surface 103 in the predetermined area 102, whereby the at least one support structure 104 protrudes from the first surface 103.

Specifically, an extending direction of the at least one support structure 104 is a longitudinal direction of the housing 101. The at least one support structure 104 is defined to be three support structures 104. The three support structures 104 are spaced with each other and are sequentially arranged on the first surface 103 in the predetermined area 102 along a transverse direction of the housing 101. The first surface 103 is the inner surface, and the transverse direction is a width direction. Thus, when cutting off the three support structures 104 later, a cutting mark left on the first surface 103 will be located inside the mobile terminal. The cutting mark can only be observed when disassembled the mobile terminal, therefore, the cutting mark will not undermine the appearance integrity of the mobile terminal. It will be apparent that, each of the at least one support structure 104 is shaped as a bridge pier, to avoid a deformation on the housing 101 in a laser cutting process. In other embodiments, the at least one support structure 104 can be other structures, as long as the at least one support structure 104 can provide a supporting, for example, the at least one support structure 104 is at least a stiffener or at least a rib. In other embodiments, other numbers of the at least one support structures can be provided.

At block S205: a laser cutter aims on and cuts the second surface in the predetermined area 102, to form a predetermined number of micro slits 1. The predetermined number of micro slits 1 are spaced with each other and are arranged side-by-side. Each of the at least one support structure 104 stretches across the predetermined number of micro slits 1, to connect the housing 101 into a whole.

Specifically, further referring to FIG. 5, an extending direction of the predetermined number of micro slits 1 is a transverse direction of the housing 101. Lasers of an optical fiber laser cutter with large power is used to cut the housing 101 from the first surface 103 to penetrate the second surface, to form the predetermined number of micro slits 1. The predetermined number of micro slits 1 is defined to be three micro slits 1. The three micro slits 1 are spaced with each other and are sequentially arranged along a longitudinal direction of the housing 101, which is also a length direction. Wherein, through a lot of experiments, the inventor develops that, through the method of embodiments of the disclosure, a width of each of the predetermined number of micro slits 1 can be in a range from 0.05 millimeters to 0.15 millimeters, that is, the predetermined number of micro slits 1 is barely visible to the naked eye, which can ensure the radio frequency signal of the antenna of the mobile terminal to pass through and can improve an integrity of outer structure of the housing 101. In this exemplary embodiment, the width of each of the predetermined number of micro slits 1 is 0.06 millimeters. Each of the at least one support structures 104 stretches across the three micro slits 1, that is each of the at least one support structure 104 covers the three micro slits 1, to form a good support structure 104. In other embodiments, other numbers of the predetermined number of micro slits 1 can be provided.

In one exemplary embodiment, an auxiliary cooling processing is performed during a laser cutting processing, to lower the temperature in the laser cutting processing, to form the remand micro slits 1. It will be apparent that, the auxiliary cooling processing can be a high-pressure nitrogen-assisted cooling processing.

At block S207: further referring to FIG. 6, a non-signal shielding material 2 is filled in each of the predetermined number of micro slits 1, to obtain a clearance area 10.

Specifically, the housing 101 having the clearance area 10 is etched. Wherein, the non-signal shielding material 2 is a material which can let the radio frequency signal passing through. It will be apparent that, the non-signal shielding material 2 can be plastic. Wherein, nano-injection filling is performed on each of the predetermined number of micro slits 1, to obtain the clearance area 10. The radio frequency signal can pass through each of the predetermined number of micro slits 1 filled with the non-signal shielding material 2, that is, the predetermined number of micro slits 1 forms to be the clearance area 10 of the antenna.

At block S209, the housing 101 having the clearance area 10 is performed by a surface treatment process.

Specifically, the housing 101 having the clearance area 10 is processed by a surface polishing process, a sandblasting process, and an anodizing process, to form an outer surface with multiple colors, to improve properties of the housing 101.

At block S211: further referring to FIG. 7, the at least one support structures 104 is cut off.

Specifically, the at least one support structures 104 is cut off by a numerical control machine, and structures on other portions of the housing 101 are simultaneously finished, to obtain a housing 100.

The method for manufacturing the clearance area of the housing provided by embodiments of the disclosure, includes cutting the housing to obtain a predetermined number of micro slits by laser, and filling a non-signal shielding material in each of the predetermined number of micro slits to form the clearance area, which can obtain the clearance area with a certain shape; and for the width of the predetermined number of micro slits is small, a ratio of the non-signal shielding material is lessening, and that can preserve the appearance integrity of the housing.

The housing provided by embodiments of the present disclosure will now be described in detail with reference to FIG. 7. It will be apparent that, the mobile terminal 200 illustrated in FIG. 7, is manufactured by the method of embodiments illustrated in FIG. 1-FIG. 6. For ease of description, only portions of the mobile terminal related with these embodiments are illustrated. Detailed technologies which are not illustrated in FIG. 7, can refer to the embodiments illustrated in FIG. 1 and FIG. 6.

In this exemplary embodiment, the mobile terminal 200 includes the housing 100 manufactured by the method of embodiments illustrated in FIG. 1-FIG. 6. The mobile terminal 200 related to this exemplary embodiment of the disclosure can be any device having functions of communication and storage, such as smart devices having a function of network like: tablet personal computers, mobile phones, electronic readers, remote controls, personal computers (PC), laptop computers, automotive equipment, network televisions, wearable equipment and etc.

In this exemplary embodiment, the housing 100 is a rear cover of a mobile terminal 200. The housing 100 is made of a signal shielding material. It will be apparent that, the signal shielding material is metal. In this exemplary embodiment, the housing 100 is made of aluminum. The housing 100 defines a predetermined area 102. The predetermined area 102 is provided with a predetermined number of micro slits 1. The predetermined number of micro slits 1 is spaced with each other and is arranged side-by-side. Each of the predetermined number of micro slits 1 is filled with a non-signal shielding material 2, to obtain a clearance area 10 configured for radio frequency signal of an antenna to pass through. It will be apparent that, the non-signal shielding material can be plastic or rubber. In this exemplary embodiment, the non-signal shielding material is plastic, for further convenient the radio frequency signal to pass through. In other exemplary embodiments, the housing 100 be a rear housing or a back cover with a border.

A extending direction of the predetermined number of micro slits 1 is a transverse direction of the housing 101. The predetermined number of micro slits 1 is defined to be three micro slits. The three micro slits 1 are spaced with each other and are sequentially arranged on the housing, along a longitudinal direction L1 of the housing, which is a length direction.

It will be apparent that, for preserve the integrity of outer structure of the housing 100, a width of each of the predetermined number of micro slits 1 can be in a range from 0.05 millimeters to 0.15 millimeters. In this exemplary embodiment, the width of each of the predetermined number of micro slits 1 is 0.06 millimeters. A distance between each two adjacent micro slits 1 is larger than the width of each of the predetermined number of micro slits 1, to further improve the integrity of outer structure of the housing 100. The housing 100 and the mobile terminal 200 provided by embodiments of the disclosure have the clearance area with a certain shape and a small area, which can preserve the integrity of outer structure of the housing.

Modules or units of the embodiments of the disclosure can be combined or separated according to actual requirements.

The foregoing description is implementations of the embodiments of the present disclosure, it should be pointed out that, for a person skilled in the art, some improvements and retouching can also be carried out in case of not out of principle of the present disclosure, these improvements and retouching are also covered within the protection of the disclosure.

What is claimed is:

1. A method for manufacturing a clearance area of a housing, comprising:
providing a housing, the housing being made of signal shielding material and defining a predetermined area, and the housing in the predetermined area having a first surface and a second surface opposite to the first surface;
forming at least one support structure on the first surface in the predetermined area, wherein the at least one support structure protrudes from the first surface;
cutting out, on the second surface, a predetermined number of micro slits by using a laser cutter, the predetermined number of micro slits penetrating from the first surface to the second surface and being spaced with each other and arranged side-by-side, each of the at least one support structure stretching across the predetermined number of micro slits to connect the housing into a whole;
filling each of the predetermined number of micro slits with a non-signal shielding material to obtain a clearance area; and
cutting off the at least one support structure.

2. The method of claim 1, wherein a width of each of the predetermined number of micro slits is in a range from 0.05 millimeters to 0.15 millimeters.

3. The method of claim 1, wherein the housing is a rear cover of a mobile terminal.

4. The method of claim 3, wherein the first surface is an inner surface of the rear cover, and the second surface is an outer surface of the rear cover.

5. The method of claim 4, further comprising manufacturing the housing, wherein the manufacturing of the housing comprises:
receiving in a mold a metal plate and pressing the metal plate to form a metal board having a predetermined shape; and
processing an inner structure and an outer shape of the metal board having the predetermined shape by a numerical control machine, to obtain the housing.

6. The method of claim 5, the receiving a metal plate in a mold and pressing the metal plate to form a metal board having a predetermined shape, comprising:
cutting the metal plate for a plurality of times, receiving in the mold the metal plate subjected to cutting, and pressing the metal plate to form the metal board having the predetermined shape.

7. The method of claim 1, wherein the at least one support structure is spaced with each other and is sequentially arranged on the first surface in the predetermined area along a transverse direction of the housing.

8. The method of claim 7, wherein the at least one support structure is at least a stiffener or at least a rib.

9. The method of claim 1, wherein cutting out, on the second surface, the predetermined number of micro slits by using the laser cutter comprises:
performing an auxiliary cooling processing during a laser cutting processing.

10. The method of claim 9, wherein the auxiliary cooling processing is a high-pressure nitrogen-assisted cooling processing.

11. The method of claim 1, wherein filling each of the predetermined number of micro slits with the non-signal shielding material to obtain the clearance area comprises:
performing nano-injection filling on each of the predetermined number of micro slits to obtain the clearance area.

12. The method of claim 1, further comprising:
after filling each of the predetermined number of micro slits with the non-signal shielding material, performing a surface treatment on the housing having the clearance area.

13. The method of claim 12, wherein the surface treatment comprises one or more selected from a group consisting of a surface polishing process, a sandblasting process, and an anodizing process.

14. The method of claim 1, wherein cutting off the at least one support structure comprises:
cutting off the at least one support structure by a numerical control machine.

15. A housing, wherein the housing is made of a signal shielding material and defines a predetermined area; the predetermined area is provided with a predetermined number of micro slits, the predetermined number of micro slits is spaced with each other and is arranged side-by-side; and each of the predetermined number of micro slits is filled with a non-signal shielding material to obtain a clearance area, the clearance area is configured for radio frequency signal of an antenna to pass through.

16. The housing of claim 15, wherein each of the predetermined number of micro slits has a width in a range from 0.05 millimeters to 0.15 millimeters.

17. The housing of claim 15, wherein the non-signal shielding material is a material configured for radio frequency signal to pass through.

18. The housing of claim 15, wherein the predetermined number of micro slits are sequentially arranged on the housing along a longitudinal direction and is spaced with each other.

19. The housing of claim 15, wherein the housing is a rear cover of a mobile terminal.

20. A mobile terminal, comprising a housing, wherein the housing is made of a signal shielding material and defines a predetermined area; the predetermined area is provided with a predetermined number of micro slits, the predetermined number of micro slits is spaced with each other and is arranged side-by-side; and each of the predetermined number of micro slits is filled with a non-signal shielding material to obtain a clearance area, the clearance area is configured for radio frequency signal of an antenna to pass through.
